(19) United States
(12) Patent Application Publication
(10) Pub. No.: US 2019/0259677 A1
(43) Pub. Date: Aug. 22, 2019

(54) DEVICE COMPRISING INTEGRATION OF DIE TO DIE WITH POLYMER PLANARIZATION LAYER

(71) Applicant: QUALCOMM Incorporated, San Diego, CA (US)

(72) Inventors: Jon LASITER, Stockton, CA (US); Ravindra Vaman SHENOY, Dublin, CA (US); Kambiz SAMADI, San Diego, CA (US); Jing XIE, San Diego, CA (US)

(21) Appl. No.: 16/135,906

(22) Filed: Sep. 19, 2018

Related U.S. Application Data
(60) Provisional application No. 62/633,565, filed on Feb. 21, 2018.

(51) Int. Cl. H01L 23/29; H01L 21/768; H01L 23/48; H01L 23/538; H01L 21/56; H01L 21/02

(52) U.S. Cl. CPC H01L 23/293; H01L 21/76877; H01L 23/481; H01L 21/02118; H01L 21/561; H01L 21/76802; H01L 23/5384

(57) ABSTRACT

A device comprising a first die, a second die coupled to a first die, and a polymer planarization layer. The second die includes a side portion and a backside portion. The polymer planarization layer is coupled to the first die and the second die such that the polymer planarization layer is coupled to the side portion and the backside portion of the second die. The polymer planarization layer includes an organic polymer. The polymer planarization layer may include a self planarizing material.

### CROSS-REFERENCE TO RELATED APPLICATION(S)

This application claims priority to and the benefit of Provisional Application No. 62/633,565, filed in the U.S. Patent and Trademark Office on Feb. 21, 2018, the entire contents of which is incorporated herein by reference as if fully set forth below in their entirety and for all applicable purpose.

### BACKGROUND

### Field

Various features relate to integrated devices, but more specifically to devices comprising integration of die to die with one or more polymer planarization layers.

### Background

FIG. 1 illustrates a wafer 102 coupled to a die 104. The coupling of the die 104 to the wafer 102 helps produce an integrated device with a very small footprint. As shown in FIG. 1, the die 104 is smaller than the wafer 102, which makes the coupling of the die 104 and the wafer 102 possible.

However, the coupling of the wafer 102 and the die 104 produces an impractical device because of the uneven surface of the device. More specifically, there is a space over the wafer 102 that is not covered by the die 104. This uneven surface makes fabricating interconnects over the wafer 102 and the die 104 very difficult or not possible. An oxide layer may be provided over the wafer 102 to even the planar surface of the combined wafer 102 and the die 104. However, the oxide layer has several drawbacks, including not being cost effective to fabricate, especially for relatively thick dies.

There is an ongoing need for providing a device that includes a wafer and die with a planarization layer. Ideally, such a device will have a smaller footprint that other known devices, and is cheaper to fabricate than other known devices.

### SUMMARY

Various features relate to integrated devices, but more specifically to devices comprising integration of die to die with one or more polymer planarization layers.

One example provides a device comprising a first die, a second die coupled to the first die, and a polymer planarization layer. The second die includes a side portion and a backside portion. The polymer planarization layer is coupled to the first die and the second die such that the polymer planarization layer is coupled to the side portion and the backside portion of the second die. The polymer planarization layer includes an organic polymer.

Another example provides an apparatus that includes a first die, a second die coupled to the first die, and means for self-planarizing layer coupled to the first die and the second die such that the means for self-planarizing layer is coupled to the side portion and the backside portion of the second die.

Another example provides a method for fabricating a device. The method provides a wafer. The method couples a second die to the wafer. The second die include a side portion and a backside portion. The method forms a polymer planarization layer over the wafer and the second die such that the polymer planarization layer is coupled to the side portion and the backside portion of the second die. The polymer planarization layer includes an organic polymer.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates a profile view of a device that includes a die and a wafer.

FIG. 2 illustrates a profile view of a device that includes a die, a wafer and a polymer planarization layer.

FIG. 3 illustrates a profile view of a device that includes a die, a wafer, another die and a polymer planarization layer.

FIG. 4 illustrates a profile view of a device that includes a first die, another die over the first die, a third die and a polymer planarization layer.

FIG. 5 illustrates a plan view of a device that includes a first die, a second die, several dies and a polymer planarization layer.

FIG. 6 illustrates a plan view of a device that includes a first die, a second die, several dies and a polymer planarization layer.

FIG. 7 illustrates a profile view of a device that includes a first die, a second die, several dies and a polymer planarization layer.

FIG. 8 (comprising FIGS. 8A-8C) illustrates an exemplary sequence for fabricating a device that includes a die, another die and a polymer planarization layer.

FIG. 9 (comprising FIGS. 9A-9C) illustrates an exemplary sequence for fabricating another device that includes a die, another die and a polymer planarization layer.

FIG. 10 illustrates a plan view of a device that includes a first die, a second die, several dies and a polymer planarization layer, that is coupled to a printed circuit board (PCB).

FIG. 11 illustrates a plan view of a device that includes a first die, a second die, several dies, a polymer planarization layer and a substrate, that is coupled to a printed circuit board (PCB).

FIG. 12 illustrates an exemplary flow diagram of a method for fabricating a device that includes a die, a wafer and a polymer planarization layer.

FIG. 13 illustrates an exemplary sequence for providing a self planarizing material over a die and another die.

FIG. 14 illustrates an exemplary sequence for providing a non-self planarizing material over a die and another die.

FIG. 15 illustrates various electronic devices that may integrate a die, a wafer, an integrated device, an integrated passive device (IPD), a device package, a package, an integrated circuit and/or PCB described herein.

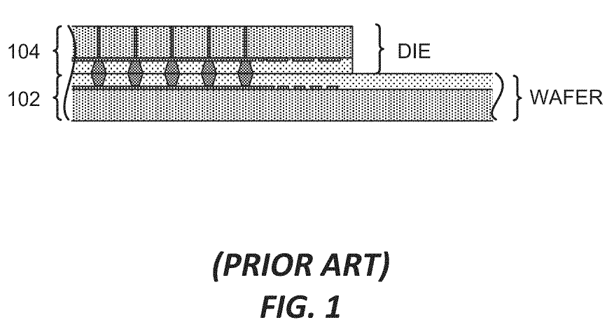

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure describes a device comprising a first die, a second die coupled to a first die and a polymer planarization layer. The second die includes a side portion and a backside portion. The polymer planarization layer is coupled to the first die and the second die such that the polymer planarization layer is coupled to the side portion and the backside portion of the second die. The polymer planarization layer includes a self-planarizing material.

### Exemplary Device Comprising a Die, a Wafer and a Polymer Planarization Layer

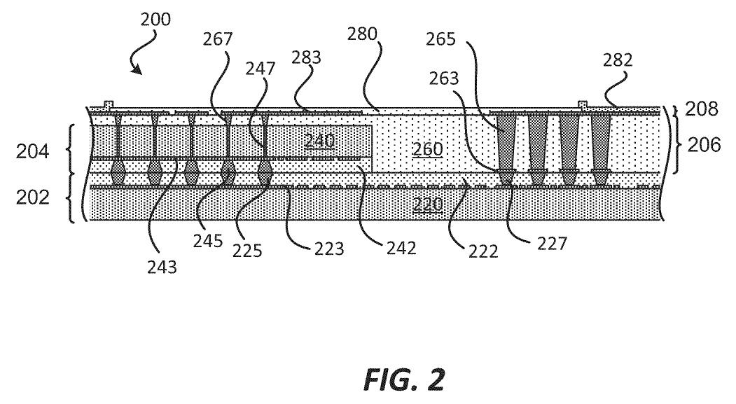

FIG. 2 illustrates a profile view of a device 200 that includes a wafer 202, a die 204, planarization layer 206, and a redistribution layer 208. The device 200 may be an integrated device. The die 204 is coupled to the wafer 202. The planarization layer 206 is coupled to the wafer 202 and the die 204. The redistribution layer 208 is coupled to the planarization layer 206. The wafer 202 may be singulated into several dies.

As will be further described below, the device 200 provides 3D (3-Dimensional) integration of a die and a wafer while also addressing topology issues for the device. The integration of a die to a wafer helps provide a device that include high density interconnects. In some implementations, a device that includes high density interconnects may be defined as a device that includes at least about 10,000 interconnects per millimeters squared (mm²) Moreover, as will be further described below, the device 200 can be fabricated in a cost-effective manner and/or cheaper than other comparable devices with similar footprints and density features. In some implementations, once the die has been integrated to a wafer, the wafer may be singulated into several dies.

The wafer 202 includes a substrate 220 (e.g., wafer substrate, silicon, glass, quartz, epoxy, or combinations thereof), at least one dielectric layer 222 (e.g., wafer dielectric layer, polyimide) and a plurality of interconnects (e.g., 223, 225, 227). The plurality of interconnects (e.g., 223, 225, 227) may include wafer interconnects. The plurality of interconnects (e.g., 223, 225, 227) may include a pad, a trace and/or vias. The wafer 202 may be a silicon wafer. The plurality of interconnects (e.g., 223, 225, 227) is formed over the substrate 220. The dielectric layer 222 is formed over the substrate 220 and the plurality of interconnects (e.g., 223, 225, 227). In some implementations, a back end of line (BEOL) process may be used to fabricate he plurality of interconnects (e.g., 223, 225, 227) and the dielectric layer 222. In some implementations, the wafer 202 may have a thickness in a range of about 100-700 micrometers (μm). It is noted that the wafer 202 may be singulated (e.g., diced, sliced), at which point the wafer 202 may be considered like a die. Thus, in some implementations, the wafer 202 may be a die (e.g., first die).

The die 204 (e.g., second die) includes a substrate 240 (e.g., die substrate, silicon, glass, quartz, epoxy, or combinations thereof), at least one dielectric layer 242 (e.g., die dielectric layer, polyimide) and a plurality of interconnects (e.g., 243, 245, 247). The plurality of interconnects (e.g., 243, 245, 247) may include die interconnects. The plurality of interconnects (e.g., 243, 245, 247) may include a pad, a trace and/or vias. The plurality of interconnects 247 travels through the substrate 240. The plurality of interconnects 247 may be through substrate vias and/or through silicon vias. The at least one dielectric layer 242 is formed over the plurality of interconnects (e.g., 243, 245). In some implementations, a back end of line (BEOL) process may be used to fabricate he plurality of interconnects (e.g., 243, 245, 247) and the dielectric layer 242. The die 204 includes side portions, a front side (e.g., active side) and a back side. In some implementations, the front side of the die 204 is the part of the die that includes the dielectric layer 242. In some implementations, the back side of the die 204 is the part of the die that includes the substrate 240. In some implementations, there may be direct coupling (e.g., without the need of solder) between the interconnects of the die 204 and the interconnects of the wafer 202. As an example, the interconnect 225 of the wafer 202 may be in direct contact with the interconnect 245 of the die 204.

In some implementations, an interconnect is an element or component of a device or package that allows or facilitates an electrical connection between two points, elements and/or components. In some implementations, an interconnect may include a trace, a via, a pad, a pillar, a redistribution metal layer, and/or an under bump metallization (UBM) layer. In some implementations, an interconnect is an electrically conductive material that may be configured to provide an electrical path for a signal (e.g., a data signal, ground or power). An interconnect may be part of a circuit. An interconnect may include more than one element or component.

The die 204 is coupled to the wafer 202 such that the at least one dielectric layer 242 faces the at least one dielectric 222 of the wafer 202. In some implementations, the front side of the die 204 is coupled to the wafer 202. The plurality of interconnects 225 of the wafer 202 is coupled to the plurality of interconnects 245 of die 204. Different implementations may use dies with different heights. In some implementations, the die 204 may have a height in a range of about 10-15 micrometers (μm).

The planarization layer 206 includes a polymer planarization layer 260 (e.g., polymer material, first polymer layer) and a plurality of interconnects (e.g., 263, 265, 267). As will be further described below, the polymer planarization layer 260 may include a self-planarizing material. In some implementations, the self-planarizing material may be part of a class of materials that is considered an organic polymer. Thus, they polymer planarization layer 260 may include an organic polymer (e.g., organic polymer planarization layer). The polymer planarization layer 260 may be a means for self-planarizing layer. The polymer planarization layer 260 enables self-planarization of the device 200 when the die 204 is coupled to the wafer 202, thus addressing and solving the topology issues when the die 204 and the wafer have different sizes and/or shapes. For example, self-planarization is enabled because the polymer material, unlike other materials (e.g., oxide, silicon oxide), that is used does not need to be etched after being disposed over the wafer 202 and the die 204, in order to create a planar surface. Self-planarizing may occur during a curing process and/or baking process of the polymer material/layer. It is noted that the polymer material (e.g., organic polymer) may be etched to create cavities in the layer to form interconnects. Another technical advantage of using a polymer material is that, unlike other materials (e.g., oxide, silicon oxide), the polymer material can be deposited over the wafer 202 and the die 204 in a single step and/or single process, thereby reducing the complexity and cost of providing the planarization layer 206. For example, using a silicon oxide (e.g., inorganic dielectric) is much more expensive, because the use of a vacuum deposition process (e.g., Plasma Enhanced Chemical Vapor Deposition) to form the silicon oxide over the wafer requires several steps. Thus, in cases where the planarization layer has to be thick, several silicon oxide layers will need to be used and/or a long deposition time will need to be used. In contrast, a single polymer layer (e.g., organic polymer) can be used to provide a planarization layer, even for a very thick planarization layer. A polymer planarization layer may be an electrically non-conductive layer.

Different implementations may use different polymer materials for the polymer planarization layer 260 with different properties and features. The polymer planarization layer 260 may be a photo-imageable polymer layer, which means the polymer planarization layer 260 may be etched using a photo imaging and/or photo lithography etching process. The photo etching of the polymer planarization layer 260 may form cavities for interconnects. These interconnects (e.g., vias) may have a minimum pitch of about 20 micrometers (μm). Thus, these interconnects (e.g., vias) may have a pitch of about 20 micrometers (μm) or greater. In some implementations, the polymer planarization layer 260 is non-photo imageable. In such instances, the polymer planarization layer 260 may be etched by using a reactive ion etching (RIE) process. In some implementations, the use of a RIE process may enable interconnects (e.g., vias) in the polymer planarization layer 260 that have a minimum pitch of about 10 micrometers (μm). Thus, these interconnects (e.g., vias) may have a pitch of about 20 micrometers (μm) or greater. In some implementations, interconnects in the polymer planarization layer 260 may have a pitch in a range of about 10-20 micrometers (μm).

The thickness of the polymer planarization layer 260 will vary according to the thickness or height of the die 204. In some implementations, the polymer planarization layer 260 may have a thickness or height in a range of about 12-50 micrometers (μm).

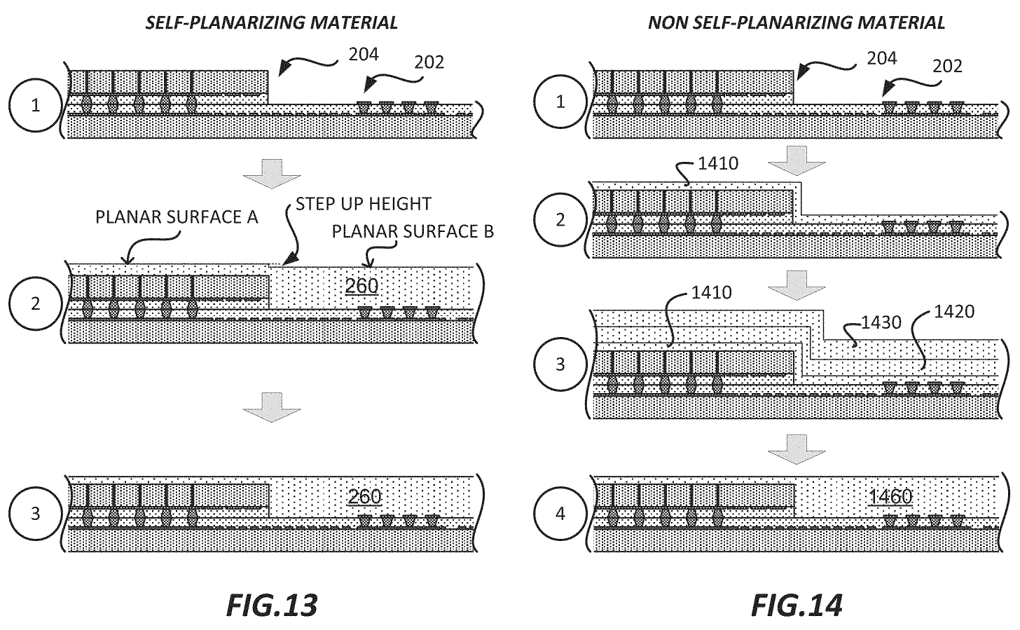

The polymer planarization layer 260 may include a polymer material that has a Young's Modulus that is less than about 1 GigaPascal and/or a hardness that is less than about 1 GigaPascal. The use of such polymer materials also provides a polymer planarization layer that is more compliant. Examples polymer materials that may be used for the polymer planarization layer 260 include Shinetsu SINR DF3170 and/or Shinetsu SINR DF4070. However different implementations may use different materials. For example, in some implementations, the polymer planarization layer 260 may be a composite material that includes one or more polymer material. As mentioned above, a polymer material is self-planarizing, especially when dealing with thicker layers. Self-planarizing materials form surfaces that are relatively flat. Thus, a chemical mechanical planarization (CMP) process may not be needed, but may still be used. This is in contrast to a polyimide (PI) layer that does not self-planarize. Further examples and advantages of a self planarizing material are described below in at least FIG. 13 and FIG. 14.

The redistribution layer 208 includes a polymer layer 280 (e.g., second polymer layer), a passivation layer 282 and a plurality of redistribution interconnects 283. The redistribution layer 208 may be a means for redistribution. The polymer layer 280 is formed over the polymer planarization layer 260. The polymer layer 280 may be made of the same material or different material as the polymer planarization layer 260. The polymer layer 280 may be a photo-imageable polymer material. The polymer layer 280 may include a self-planarizing material. The plurality of interconnects 283 may be coupled to the plurality of interconnects (e.g., 265, 267). The pitch and spacing as described for the plurality of interconnects (e.g., 265, 267) may also be applicable to the plurality of interconnects 283. The redistribution layer 208 may include several layers of the polymer layer and several layers of the plurality of interconnects 283. The plurality of interconnects 283 may include traces, pads, and/or vias.

FIG. 2 illustrates that the planarization layer 206 includes the plurality of interconnects (e.g., 263, 265, 267). The plurality of interconnects 265 may include a plurality of through polymer vias (TPV) located between the wafer 202 and the redistribution layer 208. The plurality of interconnects 267 may include a plurality of through polymer vias (TPV) located between the die 204 and the redistribution layer 208. FIG. 2 illustrates the wafer 202 has not been singulated into several dies. The wafer 202 may form as a base for the die 204.

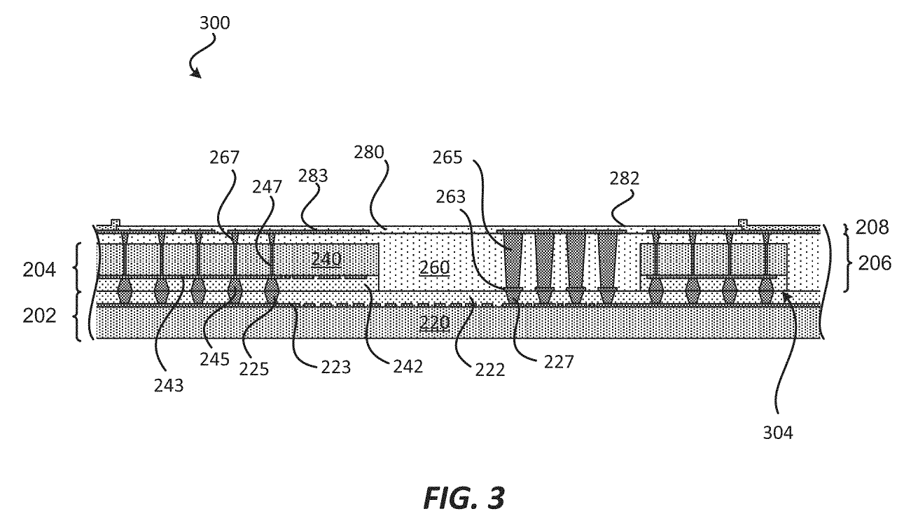

FIG. 3 illustrates a profile view of a device 300 that includes a wafer 202, a die 204, a planarization layer 206, and a redistribution layer 208. The device 300 may be an integrated device. The device 300 is similar to the device 200 and includes many of the same components, structures, devices as the device 200. The device 300 also includes a die 304. The die 304 is similar to the die 204. The die 304 may have the same materials as the die 204. The die 304 may be have the same, similar, or different functionality as the die 204. The die 304 may have the same, similar or different dimensions, sizes and/or shapes as the die 204. In some implementations, the die 304 may be considered a dielet, which in some implementations is a die that is smaller than a conventional die (e.g., smaller footprint than a conventional die). In some implementations, the die 304 may include a passive device (e.g., inductor, capacitor, trench capacitor), which may help with power delivery. The die 304 may include high voltage silicon circuits to provide improve power management. The die 304 may include radio frequency components and/or optical photonics.

The die 304 is coupled to the wafer 202. The planarization layer 206 is coupled to the wafer 202, the die 204 and the die 304. In some implementations, the die 304 is co-planar to the die 204. The die 304 may have a different height or thickness than the die 204. However, the polymer planarization layer 260 still provides a planar surface over which the redistribution layer 208 can be formed. The wafer 202 may be singulated into several dies. The wafer 202 may form as a base for the die 204 and the die 304.

Different implementations may provide dies with different sizes. In some implementations, the die 204 may have a size (e.g., footprint) in the range of 3 millimeters (mm)×3 millimeters (mm) to 20 millimeters (mm)×20 millimeters (mm) In some implementations, the die 304 may have a size (e.g., footprint) in the range of 0.4 mm×0.2 mm to 10 mm×20 mm.

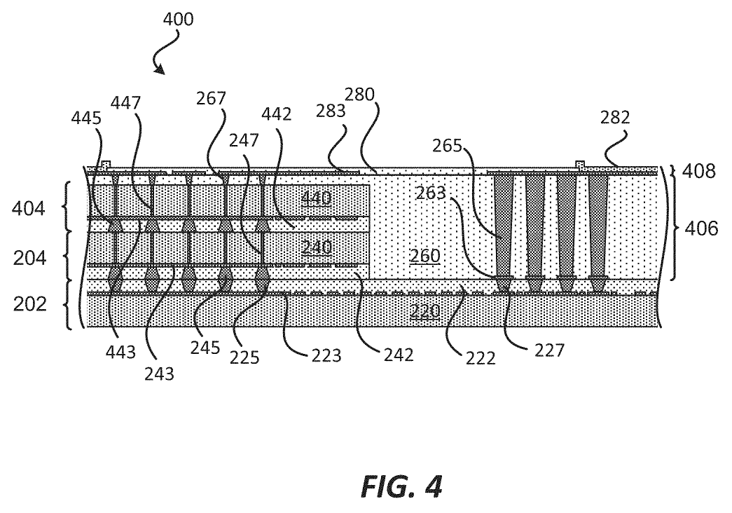

FIG. 4 illustrates a profile view of a device 400 that includes a wafer 202, a die 204, planarization layer 406, and a redistribution layer 408. The device 400 may be an integrated device. The device 400 is similar to the device 200 and includes many of the same components, structures, devices as the device 200. The device 400 also includes a die 404. The die 404 is similar to the die 204. The die 404 may have the same materials as the die 204. The die 404 may be have the same, similar, or different functionality as the die 204. The die 404 may have the same, similar or different dimensions, sizes and/or shapes as the die 204. In some implementations, the die 404 may be considered a dielet, which in some implementations is a die that is smaller than a conventional die. In some implementations, the die 404 may include a passive device (e.g., inductor, capacitor, trench capacitor), which may help with power delivery. The die 404 may include high voltage silicon circuits to provide improve power management. The die 404 may include radio frequency components and/or optical photonics.

The die 404 includes a dielectric layer 442 (e.g., die dielectric layer, polyimide), a substrate 440, a plurality of interconnects 445 (e.g., via, pad, trace) formed in the dielectric layer 442, and a plurality of interconnects 447 (e.g., via) formed in the substrate 440. The plurality of interconnects 447 is coupled to the interconnects 267 and the plurality of interconnects 445. The plurality of interconnects 445 is coupled to the plurality of interconnects 247.

The die 204 and the die 404 are located in the planarization layer 406. The die 404 is coupled to die 204. The die 404 is over the die 204. The planarization layer 406 is coupled to the wafer 202, the die 204 and the die 404. The die 404 may have the same or different height or thickness than the die 204. However, the polymer planarization layer 260 still provides a planar surface over which the redistribution layer 408 can be formed. It is noted that the device (e.g., 200, 300, 400) may include more than two dies, where some of the dies are over other dies and some of the dies are co-planar to other dies in the planarization layer. The wafer 202 may form as a base for the die 204.

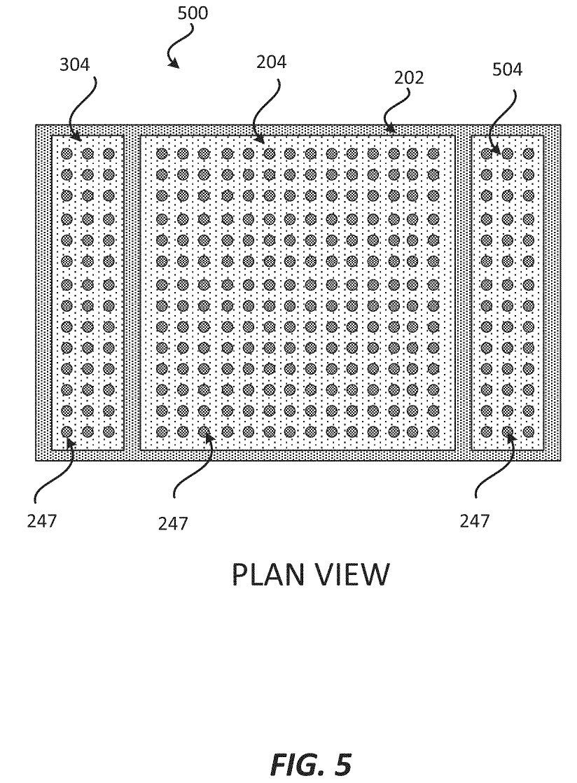

FIG. 5 illustrates a plan view of a device 500 that includes a wafer 202, a die 204, planarization layer 206 (which is not visible), a die 304 and a die 504. The die 504 may be the same or similar to the die 304. The die 204, the die 304 and the die 504 are located in the planarization layer 206 of the device 500. The die 204 is located between the die 304 and the die 504. The wafer 202 has been singulated into several dies. FIG. 5 illustrates the wafer 202 as a single die that forms as a base for the die 204, the die 304 and the die 504.

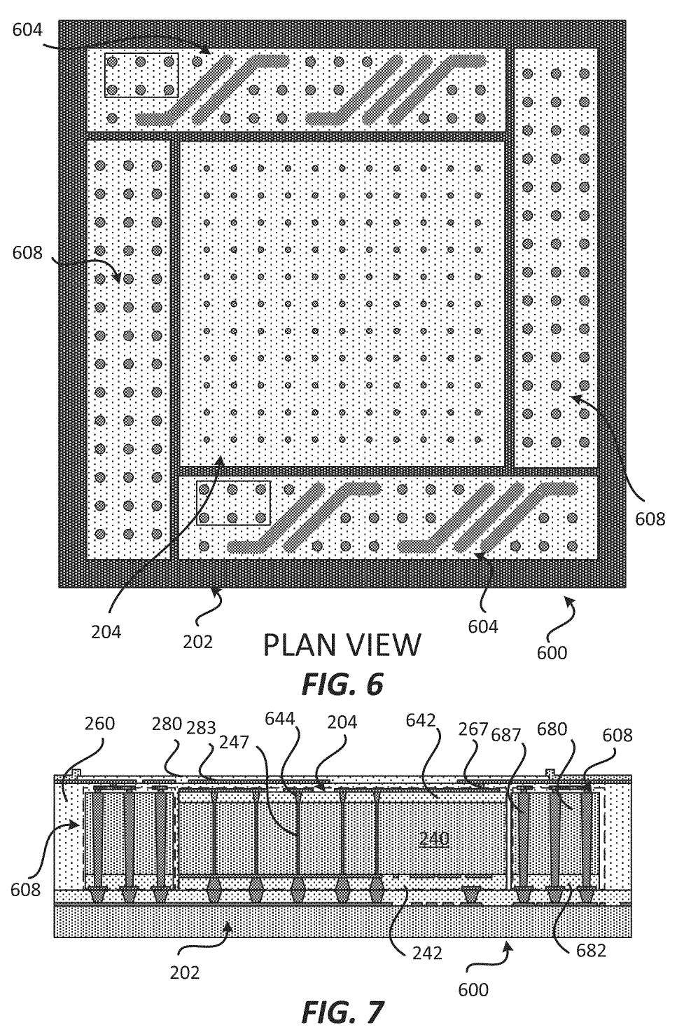

FIG. 6 illustrates a plan view of a device 600 that includes a wafer 202, a die 204, and planarization layer 206 (which is not visible), dies 608 and dies 604. The die 604 and/or the die 608 may be the same or similar to the die 304. The die 204, the dies 608 and the dies 604 are located in the planarization layer 206 of the device 600. The die 204 is located between the dies 608 and the dies 604. The dies 608 and the die 604 laterally surround the die 204.

FIG. 6 illustrates that some of dies (e.g., 604) includes traces (e.g., diagonal traces) and that some of the dies may be configured to include a passive device. For example, the die 604 may be configured such that a portion of the interconnects (e.g., vias, traces, pad) may function like one or more passive devices (e.g., inductor). In some implementations, the dies (e.g., 604, 608) may included embedded discrete passive devices (e.g., discrete inductor).

FIG. 7 illustrates a profile view of the device 600 that includes the wafer 202, the die 204, the polymer planarization layer 260, the die 608, a polymer layer 280 and a plurality of interconnects (e.g., 267, 283). The die 604 is not shown in FIG. 7. The die 608 includes a dielectric layer 682, a substrate 680 and a via 687. The die 608 may be a dielet, which may be a die with a smaller footprint than the die 204. The via 687 travels through the substrate 680 and the dielectric layer 682. In some implementations, the die 608 may be similar to the die 204 and/or the die 304 as described in FIG. 2.

As shown in FIG. 7, the die 204 includes a dielectric layer 642, and a via 644 that travels through the dielectric layer 642. The via 644 may be coupled to the via 247 located in the substrate 240.

FIGS. 6 and 7 illustrate a device 600 is compact and has a small footprint, enabling the device to be implemented in very small devices, such mobile devices.

It is noted that FIGS. 2, 3, 4, 5, 6 and 7 illustrate devices (e.g., 200, 300, 400, 500, 600), which may be referred as 3D integrated devices, that include wafers. In some implementations, these wafers may be singulated, which may be result in the wafers being considered as a die. In such instances, these devices (e.g., 200, 300, 400, 500, 600) may illustrate a 3D integrated device that includes a first die (e.g., 202), a second die (e.g., 204), and a polymer planarization layer 260. In FIGS. 6-7, the wafer 202 has been singulated into several dies (however only one die of the singulated wafer is shown). The singulated wafer 202 (e.g., die) may form as a base for the die 204, the die 604 and the die 608.

The devices (e.g., 200, 300, 400, 500, 600) described in the disclosure may be used for WiFi stack, L3/L4 memory stack (e.g., system cache), 1.8V I/O stack, millimeter wave (mmW) intermediate frequency (IF) stack (e.g., mmW modem and IF chip), and/or a 5G stack.

### Exemplary Sequence for Fabricating a Device Comprising a Die, a Wafer and a Polymer Planarization Layer

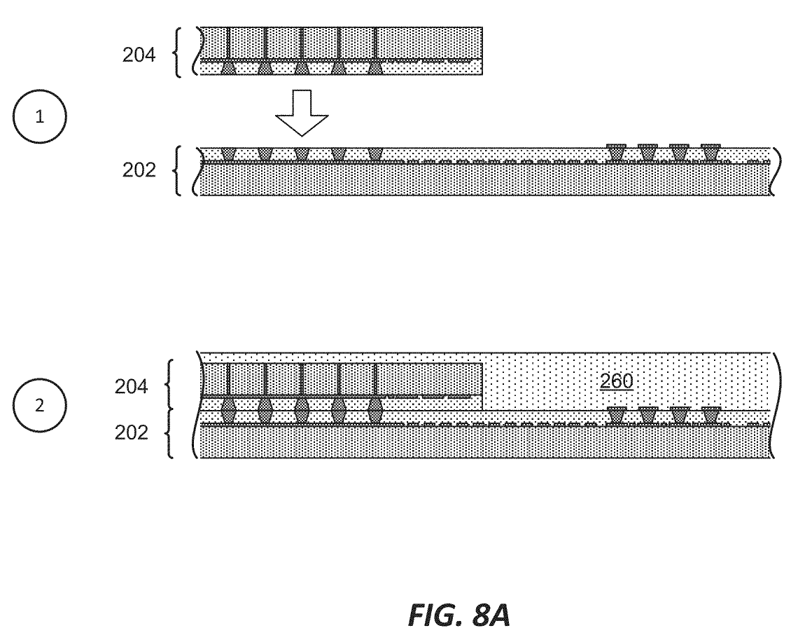

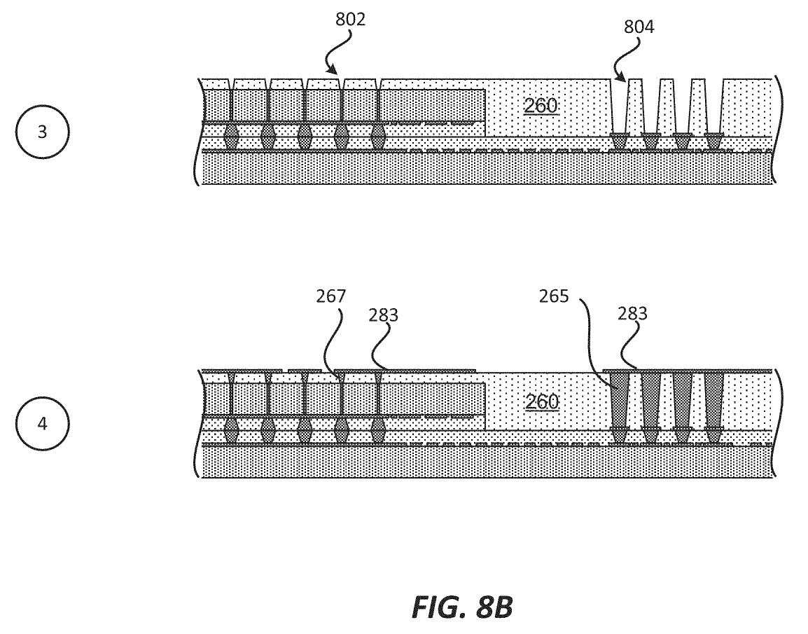

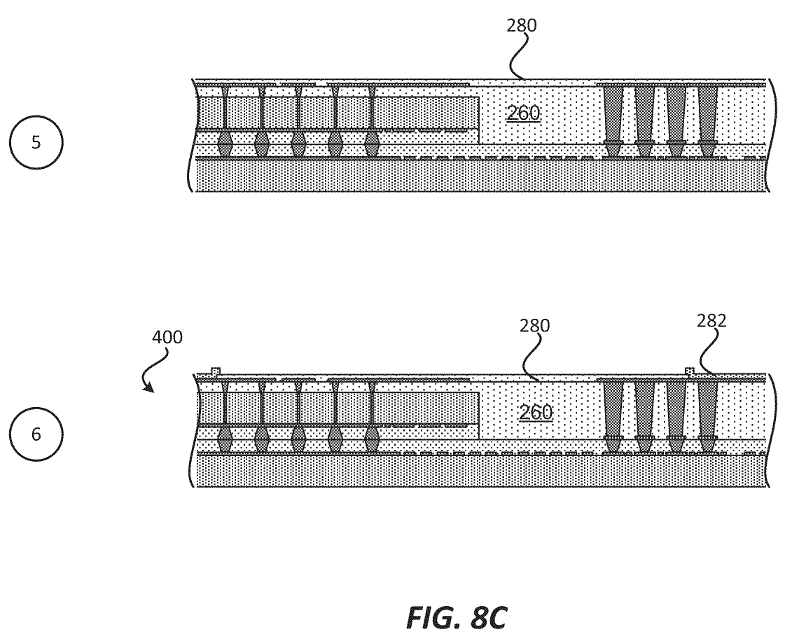

In some implementations, fabricating a device that includes a die, a wafer and a polymer planarization layer includes several processes. FIG. 8 (which includes FIGS. 8A-8C) illustrates an exemplary sequence for providing or fabricating a device that includes a die, a wafer and a polymer planarization layer. In some implementations, the sequence of FIGS. 8A-8C may be used to provide or fabricate the device of FIG. 2 and/or other devices described in the present disclosure. For example, the sequence of FIGS. 8A-8C may be used to fabricate the devices 200, 300, 400, 500 and/or 600. FIGS. 8A-8C will illustrate the fabrication of device 200.

It should be noted that the sequence of FIGS. 8A-8C may combine one or more stages in order to simplify and/or clarify the sequence for providing or fabricating a device that includes a die, a wafer and a polymer planarization layer. In some implementations, the order of the processes may be changed or modified. In some implementations, one or more of processes may be replaced or substituted without departing from the spirit of the disclosure.

Stage 1, as shown in FIG. 8A, illustrates a die 204 being coupled to a wafer 202. The die 204 may be coupled to the wafer 202 by using a bonding process. In some implementations, many dies may be coupled to the wafer 202. In some implementations, there may be a direct bonding (e.g., bonding without a need of solder) between the interconnects of the wafer 202 and the interconnects of the die 204. For example, there may be direct contact between an interconnect of the wafer 202 and an interconnect of the die 204, when the die 204 is coupled to the wafer 202.

Stage 2 illustrates a state after a polymer planarization layer 260 is formed (e.g., disposed, deposited) over the wafer 202 and the die 204. A lamination process may be used to form the polymer planarization layer 260. Examples of polymers materials were previously described above. The polymer planarization layer 260 may be self-planarizing material. The polymer planarization layer 260 is formed such that the polymer planarization layer 260 is coupled to the wafer 202 and the side portion and back side of the die 204. In some implementations, there may be several dies (e.g., 304, 504). In such instances, the polymer planarization layer 260 may be formed over the side portions and/or the back side of those dies.

Stage 3, as shown in FIG. 8B, illustrates a state after cavities (e.g., 802, 804) are formed in the polymer planarization layer 260. Different implementations may use different implementations for forming the cavities. In some implementations, a photolithography process may be use to form cavities in the polymer planarization layer 260. In some implementations, a reactive ion etching (RIE) process may be used to form cavities in the polymer planarization layer 260.

Stage 4 illustrates a state after a plurality of interconnects (e.g., 265, 283, 267, 283) is formed in, on and/or over the polymer planarization layer 260. One or more plating processes may be used to form the plurality of interconnects.

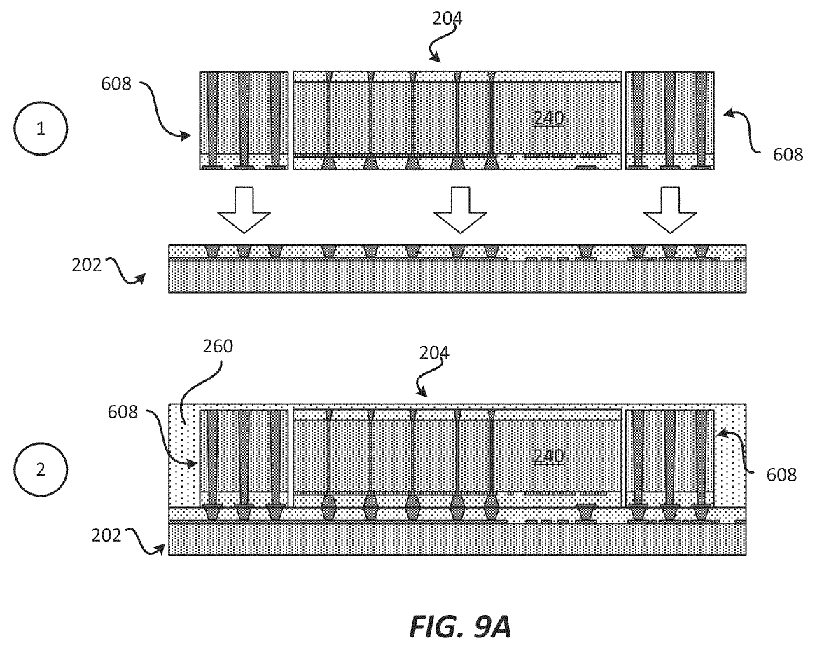

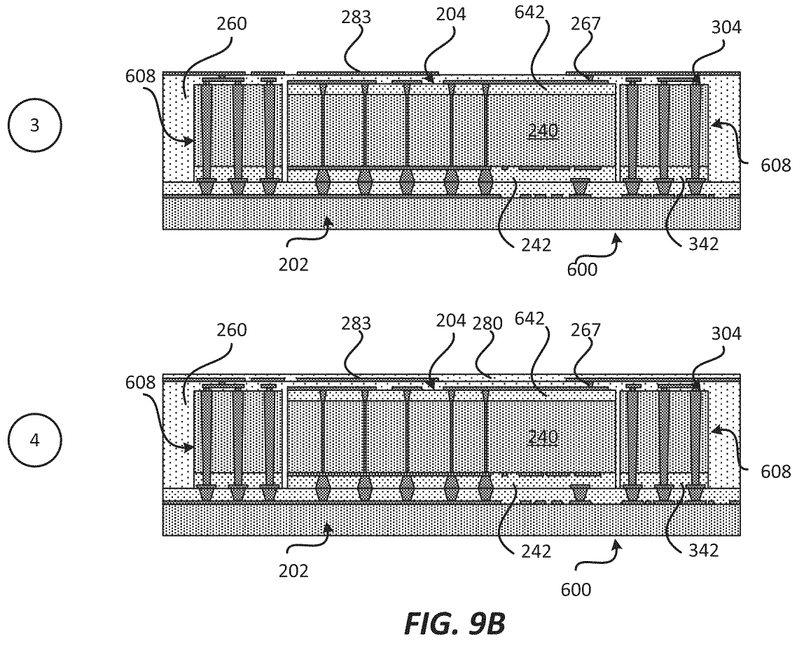

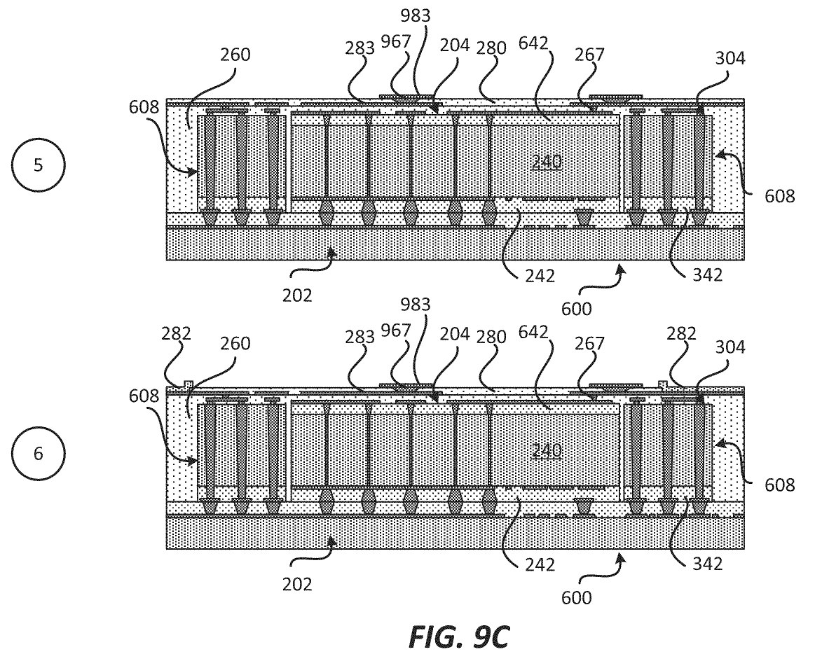

Stage 5, as shown in FIG. 8C, illustrates a state after a polymer layer 280 is formed (e.g., disposed, deposited) over the polymer planarization layer 260. A lamination process may be used to form the polymer layer 280. The polymer layer 280 may be the same material or a different material as the polymer planarization layer 260. The polymer layer 280 may encapsulate the plurality of interconnects 283. In some implementations, a plurality of interconnects (e.g., traces, vias, pads) may be formed over the polymer layer 280. These plurality of interconnects (e.g., 283) may be redistribution interconnects. In some implementations, additional polymer layer(s) may be formed over the plurality of interconnects. One or more bumps (e.g., pillars, solder interconnects) may be coupled to the plurality of interconnects. An example of forming a redistribution layer (e.g., means for redistribution) and bumping are illustrated and described in FIGS. 9A-9C.

Stage 6 illustrates a state after a passivation layer is formed over the polymer layer 280 and/or the plurality of interconnect 283.

In some implementations, the combination of the wafer 202, the die 204 and the polymer planarization layer 260 may be sliced or diced into smaller sizes and/or pieces. In such instances, the wafer (e.g., 202) may be considered a die. For example, the wafer may be singulated into several dies. It is noted that singulation not only divides the wafer, but also any material and/or components coupled to the wafer. Thus, singulation of a wafer as used in the disclosure, may also include singulation of the polymer planarization layer, the polymer layer, and/or the passivation layer.

A lamination process is used to form the polymer layer and the interconnects. However, it is noted that other types of processes may be used to form the polymer layer and interconnects. For example, other deposition techniques such as extrusion, spin-on may be used to form the polymer layer and interconnects.

### Exemplary Sequence for Fabricating a Device Comprising a Die, a Wafer and a Polymer Planarization Layer

FIG. 9 (which includes FIGS. 9A-9C) illustrates an exemplary sequence for providing or fabricating another device that includes a die, a wafer and a polymer planarization layer. In some implementations, the sequence of FIGS. 9A-9C may be used to provide or fabricate the device of FIGS. 6-7 and/or other devices described in the present disclosure. For example, the sequence of FIGS. 9A-9C may be used to fabricate the devices 200, 300, 400, 500 and/or 600. The sequence of FIGS. 9A-9C may be similar to the sequence described for FIGS. 8A-8C. FIGS. 9A-9C will illustrate the fabrication of device 600.

It should be noted that the sequence of FIGS. 9A-9C may combine one or more stages in order to simplify and/or clarify the sequence for providing or fabricating a device that includes a die, a wafer and a polymer planarization layer. In some implementations, the order of the processes may be changed or modified. In some implementations, one or more of processes may be replaced or substituted without departing from the spirit of the disclosure.

Stage 1, as shown in FIG. 9A, illustrates a die 204 and dies 608 being coupled to a wafer 202. The die 204 and the dies 608 may be coupled to the wafer 202 by using one or more bonding processes. The die 204 and the dies 608 may be coupled to the wafer simultaneously or sequentially. In some implementations, there may be a direct bonding (e.g., bonding without a need of solder) between the interconnects of the wafer 202 and the interconnects of the die 204 and/or die 608. For example, there may be direct contact between an interconnect of the wafer 202 and an interconnect of the die 608, when the die 608 is coupled to the wafer 202.

Stage 2 illustrates a state after a polymer planarization layer 260 is formed (e.g., disposed, deposited) over the wafer 202, the die 204, and dies 608. A lamination process may be used to form the polymer planarization layer 260. Examples of polymers materials were previously described above. The polymer planarization layer 260 is formed such that the polymer planarization layer 260 is coupled to the wafer 202 and the side portion and back side of the die 204 and dies 608. In some implementations, there may be several dies (e.g., 304, 504). In such instances, the polymer planarization layer 260 may be formed over the side portions and/or the back side of those dies also.

Stage 3, as shown in FIG. 9B, illustrates a state after a plurality of interconnects (e.g., 265, 267, 283) is formed in, on and/or over the polymer planarization layer 260. One or more plating processes may be used to form the plurality of interconnects. The plurality of interconnects may be formed after cavities are formed in the polymer planarization layer 260. Different implementations may use different implementations for forming the cavities. In some implementations, a photolithography process may be use to form cavities in the polymer planarization layer 260. In some implementations, a reactive ion etching (RIE) process may be used to form cavities in the polymer planarization layer 260.

Stage 4 illustrates a state after a polymer layer 280 is formed over the polymer planarization layer 260 and/or the plurality of interconnect (e.g., 283).

Stage 5, as shown in FIG. 9C, illustrates a state after a plurality of interconnects (e.g., 967, 983) are formed in, on and/or or over the polymer layer 280. One or more plating processes may be used to form the plurality of interconnects. The plurality of interconnects may be formed after cavities are formed in the polymer layer 280.

Stage 6 also illustrates a passivation layer (e.g., 282) formed over the polymer layer 280 and the plurality of interconnects.

In some implementations, the combination of the wafer 202, the die 204, the dies 608, and the polymer planarization layer 260 may be sliced or diced (e.g., singulated) into smaller sizes and/or pieces. In such instances, the wafer (e.g., 202) may be considered a die.

### Exemplary Devices Comprising a First Die, a Second Die and a Polymer Planarization Layer

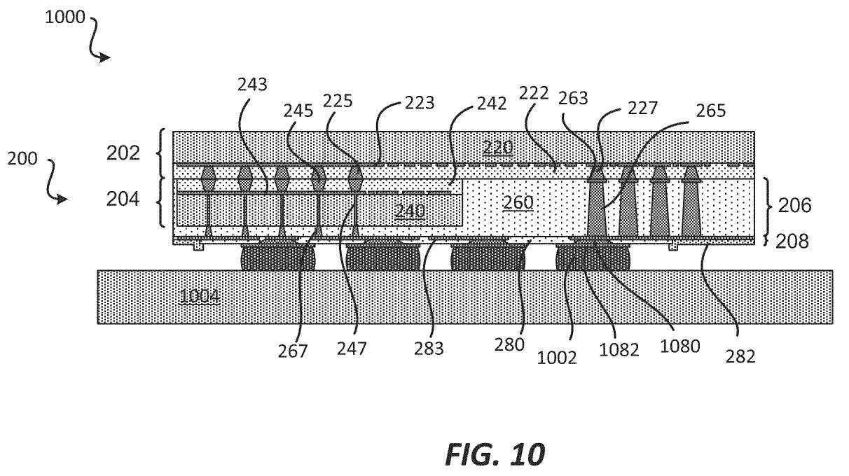

FIG. 10 illustrates a profile view of a device 1000 that includes the device 200 that has been singulated. Singulation may include dicing and/or dicing, by using a mechanical process (e.g., saw) and/or a laser process. In some implementations, the device 1000 is an integrated package. The device 1000 may include the die 202 (e.g., first die), the die 204 (e.g., second die), the polymer planarization layer 206 (e.g., means for self-planarizing layer), and the redistribution layer 208 (e.g., means for redistribution). The die 202 may be from a singulated wafer. The redistribution layer 208 includes the polymer layer 280 (e.g., second polymer layer) and a plurality of interconnects, such as interconnects 283, via 1080, and pad 1082. The device 1000 is coupled to a printed circuit board (PCB) 1004 through a plurality of solder interconnects 1002 (e.g., solder balls).

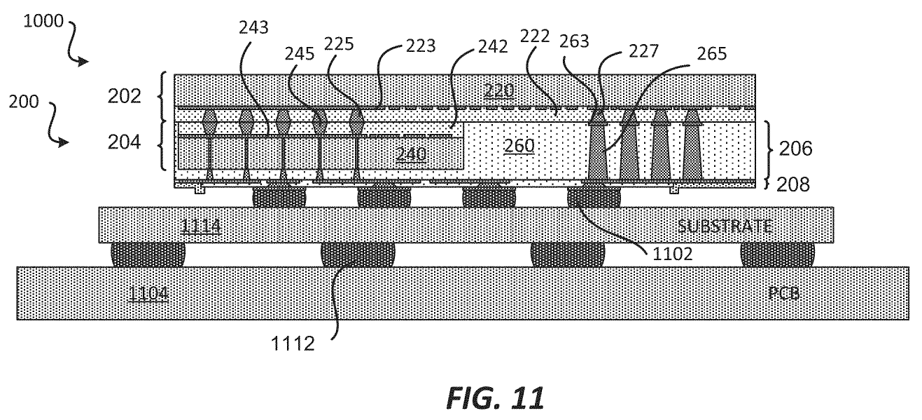

FIG. 11 illustrates a profile view of a device 1100 that includes the device 200 that has been singulated. Singulation may include dicing and/or dicing, by using a mechanical process (e.g., saw) and/or a laser process. In some implementations, the device 1100 is an integrated package. The device 1100 may include the die 202 (e.g., first die), the die 204 (e.g., second die), the polymer planarization layer 206 (e.g., means for self-planarizing layer), the redistribution layer 208 (e.g., means for redistribution), and the substrate 1114. The redistribution layer 208 includes the polymer layer 280 (e.g., second polymer layer) and a plurality of interconnects, such as interconnects 283, via 1080, and pad 1082. The redistribution layer 208 is coupled to the substrate 1114 through the plurality of solder interconnects 1102 (e.g., solder balls, pillar and solder). The device 1100 is coupled to a printed circuit board (PCB) 1104 through a plurality of solder interconnects 1112 (e.g., solder balls). The plurality of solder interconnects 1112 is coupled to the substrate 1114.

FIGS. 10 and 11 illustrate devices that use the device 200. However, the device 1000 and the device 1100 may include any of the other devices described in the disclosure, such as devices 300, 400, 500 and/or 600.

### Exemplary Flow Diagram of a Method for Fabricating a Device Comprising a Die, a Wafer and a Polymer Planarization Layer

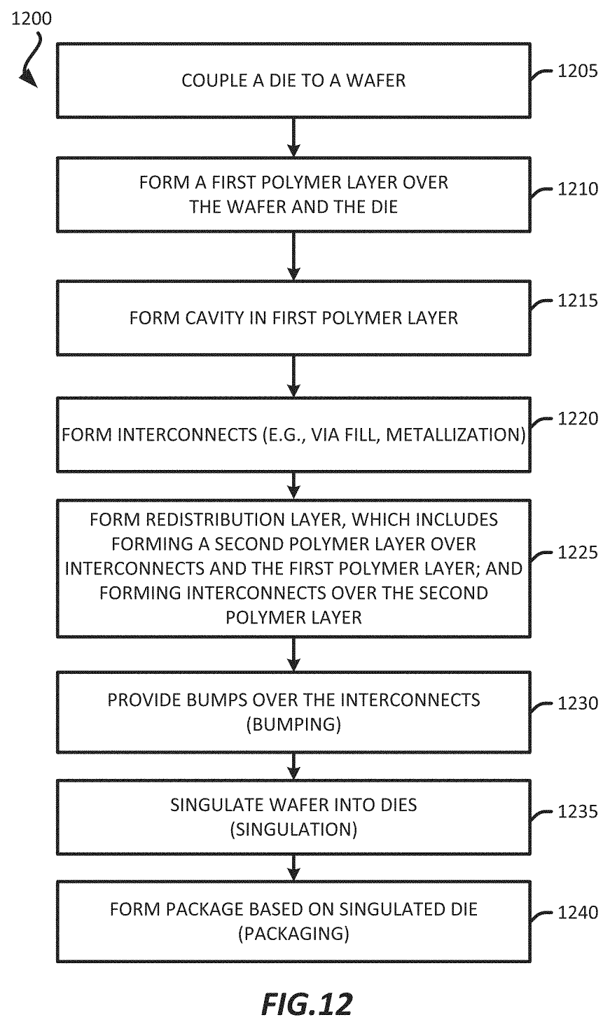

In some implementations, a device that includes a die, another die and a polymer planarization layer includes several processes. FIG. 12 illustrates an exemplary flow diagram of a method 1200 for providing or fabricating a device that includes a die, another and a polymer planarization layer. In some implementations, the method 1200 of FIG. 12 may be used to provide or fabricate the device of FIG. 2 and/or other devices described in the present disclosure. For example, the method of FIG. 12 may be used to fabricate the devices 200, 300, 400, 500 and/or 600.

It should be noted that the sequence of FIG. 12 may combine one or more processes in order to simplify and/or clarify the method for providing or fabricating a device that includes a die, another die and a polymer planarization layer. In some implementations, the order of the processes may be changed or modified.

The method couples (at 1205) the die 204 to the wafer 202. The die 204 may be coupled to the wafer 202 by using a bonding process. The method may also couple other dies to the wafer 202 and/or over the die 204.

The method forms (at 1210) a polymer planarization layer 260 (e.g., first polymer layer) over the wafer 202 and the die 204. A lamination process may be used to form the polymer planarization layer 260. Examples of polymers materials were previously described above. The polymer planarization layer 260 is formed such that the polymer planarization layer 260 is coupled to the wafer 202 and the side portion and back side of the die 204. In some implementations, there may be several dies (e.g., 304, 504). In such instances, the polymer planarization layer 260 may be formed over the side portions and/or the back side of those dies.

The method forms (at 1215) cavities (e.g., 802, 804) in the polymer planarization layer 260 (e.g., first polymer layer). Different implementations may use different processes for forming the cavities. In some implementations, a photolithography process may be use to form cavities in the polymer planarization layer 260. In some implementations, a reactive ion etching (RIE) process may be used to form cavities in the polymer planarization layer 260.

The method forms (at 1220) a plurality of interconnects (e.g., 265, 283, 267, 283) in, on and/or over the polymer planarization layer 260. One or more plating processes may be used to form the plurality of interconnects.

The method forms (at 1225) a redistribution layer (e.g., means for redistribution) over the polymer planarization layer 260 (e.g., means for self-planarizing layer). In some implementations, forming a redistribution layer (e.g., 208) includes forming a polymer layer 280 (e.g., second polymer layer) over the polymer planarization layer 260. A lamination process may be used to form the polymer layer 280. The polymer layer 280 may be the same material or a different material as the polymer planarization layer 260. The polymer layer 280 may encapsulate the plurality of interconnects 283. In some implementations, forming a redistribution layer may also include forming a plurality of interconnects (e.g., vias, pads, traces) over the polymer layer 280 (e.g., second polymer layer). Examples of forming a redistribution layer are illustrated and described in at least FIGS. 9A-9C. A passivation layer may also be formed over the polymer layer 280 and/or the plurality of interconnects (e.g., 283). In some implementations, the method may form additional interconnects and/or polymer layers before forming a passivation layer.

The method provides (at 1230) bumps over the interconnects. The bumps may include pillars (e.g., copper pillars) and/or solder interconnects (e.g., solder balls). This process may be known as bumping.

The method singulates (at 1235) the wafer into several dies. In some implementations, singulating the wafer may produce several devices (e.g., 1000) that include a first die, a second die, a polymer planarization layer, and a redistribution layer. These singulated devices may be integrated packages. These packages may have smaller footprints and thickness than other packages. Singulation may include mechanically dicing (e.g., using a saw) the wafer and/or using a laser process to cut the wafer into dies.

The method may further package (at 1040) the singulated dies by forming an encapsulation layer over the singulated devices and coupling them to substrates and/or printed circuit board (PCB).

### Self-Planarizing Materials

In some implementations, self planarizing materials belong in a class of material that are self leveling when disposed over an object. The self leveling of the self planarizing material may occur prior to a curing process (e.g., baking) and/or during the curing process of the self planarizing material. A self planarizing material may have different properties relative to a non-self planarizing material.

A self planarizing material may have a viscosity (e.g., prior to curing and/or during curing) that is lower than a viscosity of a non-self planarizing material (e.g., polyimide). As mentioned above, examples of a self planarizing material include Shinetsu SINR DF3170 and/or Shinetsu SINR DF4070. In some implementations, a self planarizing material may include a viscosity during curing that is comparable to or lower than Shinetsu SINR DF3170 and/or Shinetsu SINR DF4070. However, the viscosity of a self planarizing material may vary from material to material.

Another potentially relevant property of a self planarizing material may be the glass transition temperature (Tg) of the self planarizing material. In some implementations, a glass transition temperature (Tg) may include a range of temperatures in which the material transitions from a hard and relatively brittle glassy state into a viscous or rubbery state as the temperature increases. The glass transition temperature of a material is lower than the melting temperature of the material. In some implementations, the self planarizing material may have a Tg that starts in a range around 170 degrees Celsius (e.g., 170 degrees C. or higher, but less than its melting temperature). Thus, a self planarizing material may have a Tg that includes a temperature of 170 degrees Celsius. However, the Tg of a self planarizing material may be more or less than described above. In contrast, a non-self planarizing polyimide has a Tg that starts at 360 degrees Celsius or higher.

Other exemplary properties for a self planarizing material may include having a coefficient of thermal expansion (CTE) of about 170 parts per million per degree Centigrade (ppm/C), an elongation of about 40 percent, a loss tangent of about 0.010, a water absorption of less than about 0.1 percent, and/or a tensile strength of about 10 megapascals (MPa).

As described above, self planarizing materials provide technical advantages over non-self planarizing materials. For example, the use of self-planarizing materials may reduce the number of steps and/or processes needed to fabricate the device(s) described in the present disclosure. FIG. 13 and FIG. 14 illustrate respectively, a process that uses a self planarizing material and a process that uses a non-self planarizing material.

Stage 1 of FIG. 13 illustrates a state after the die 204 has been coupled to the wafer 202. An example of the coupling is described at stage 1 of FIG. 8A.

Stage 2 of FIG. 13 illustrates a state after a self planarizing material (e.g., polymer planarization layer 260) has been disposed over the die 204 and the wafer 202. Stage 2 may illustrate a state prior, during, or after a curing process (e.g., baking process) of the self planarizing material. As shown at stage 2 of FIG. 13, the use of a self planarizing material may result in a step up height in the polymer planarization layer 260. In some implementations, the step-up height may be a height difference or a gap difference between the planar surface A and the planar surface B of the polymer planarization layer 260. In some implementations, the step up height may be proportional and/or based on the height or thickness of the die 204. In some implementations, the step up height (e.g., height difference) may be about 10 percent or less (e.g., 5-10 percent) of the height or thickness of the die 204. In instances where several dies are stacked up on top of each die, the step up height may be about 10 percent or less of the combined height or thickness of the stacked dies. In some implementations, the step up height is small enough that no further action is necessary to smooth out the planar surface of the polymer planarization layer 260. In some implementations, a redistribution layer 208 may be formed over the planar surface of the polymer planarization layer 260 that includes a step up height. Thus, in some implementations, the devices 200, 300, 400, 500 and/or 600 may include a polymer planarization layer 260 with a step up height, as shown in stage 2 of FIG. 13. In some implementations, the process of forming the redistribution layer 208 will adjust for the step up height such that the redistribution layer 208 may be relatively planar. For example, the polymer layer 280 may be thick enough to offset the step up height of the polymer planarization layer 260.

However, in some implementations, additional processing to further planarize the planar surface of the polymer planarization layer 260 may be performed. For example, a chemical mechanical planarization (CMP) process may be applied to the polymer planarization layer 260 to form a flatter surface (e.g., surface without the step up height, surface with a smaller step up height).

Stage 3 of FIG. 13 illustrates a state after a planarizing process (e.g., CMP process) has been performed on the polymer planarization layer 260. This planarizing process may be optional when the polymer planarization layer 260 includes a self planarizing material, since any step up height may be negligible.

As mentioned above, FIG. 14 illustrates a process that uses a non-self planarizing material. Stage 1 of FIG. 14 illustrates a state after the die 204 has been coupled to the wafer 202.

Stage 2 of FIG. 14 illustrates a state after an oxide layer 1410 has been deposited over the die 204 and the wafer 202. The oxide layer 1410 is a non-self planarizing material. The oxide layer 1410 follows the contours of the die 204 and the wafer 202.

Stage 3 of FIG. 14 illustrates a state after the oxide layers 1420 and 1430 have been deposited over the oxide layer 1410. Multiple oxide layers and/or deposition processes may be required because of the thickness of the die 204. In addition, there is a very thick oxide layer(s) above the die 204, which will need to be planarize.

Stage 4 of FIG. 14 illustrates a state after a planarizing process (e.g., CMP process) has been performed on the oxide layer 1460. In some implementations, the oxide layer 1460 may cumulatively represent the oxide layers 1410, 1420 and 1430 after the planarizing process. Thus, the oxide layer 1460 may include several oxide layers.

Comparing the process of using a non-self planarizing material (as shown in FIG. 14) with a process that uses a self planarizing material (as shown in FIG. 13), and it is clear how the self planarizing material is better than the non-self planarizing material. One, the self planarizing material produces a much smaller step up height, that may or may not require a planarizing process. Thus, the use of a self planarizing material may result in less material waste. Two, the self-planarizing material uses less steps to form the layer over the die 204 and the wafer 202. Thus, the self planarizing material may be more cost effective overall, accounting for material and process.

For example, using a silicon oxide (e.g., oxide layer) is much more expensive, because the use of a vacuum deposition process (e.g., Plasma Enhanced Chemical Vapor Deposition) to form the silicon oxide over the wafer requires several steps. Thus, in cases where the planarization layer has to be thick, several silicon oxide layers will need to be used and/or a long deposition time will need to be used. In contrast, a single self planarizing material layer can be used to provide a planarization layer, even for a very thick planarization layer.

### Exemplary Electronic Devices

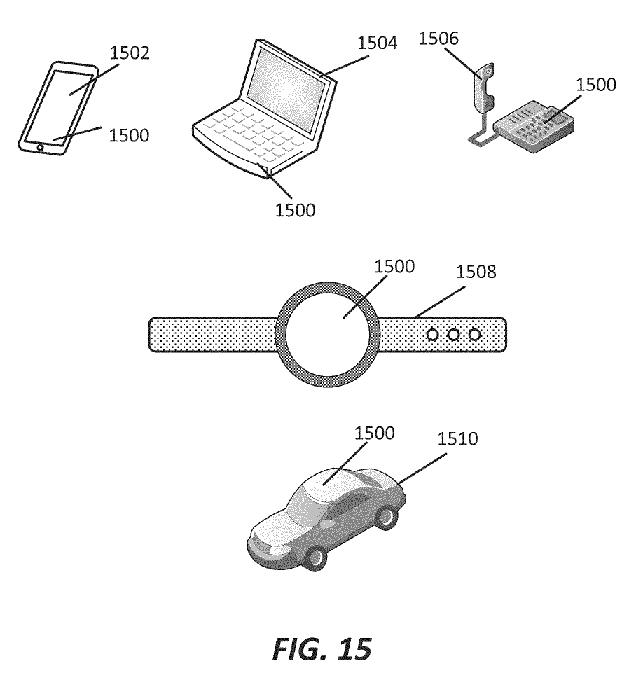

FIG. 15 illustrates various electronic devices that may be integrated with any of the aforementioned device, integrated device, integrated circuit (IC) package, integrated circuit (IC) device, semiconductor device, integrated circuit, die, interposer, package or package-on-package (PoP). For example, a mobile phone device 1502, a laptop computer device 1504, a fixed location terminal device 1506, a wearable device 1508, or automotive vehicle 1510 may include a device 1500 as described herein. The device 1500 may be, for example, any of the devices and/or integrated circuit (IC) packages described herein. The devices 1502, 1504, 1506 and 1508 and the vehicle 1510 illustrated in FIG. 15 are merely exemplary. Other electronic devices may also feature the device 1500 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 2-7, 8A-8C, 9A-9C and/or 10-15 may be rearranged and/or combined into a single component, process, feature or function or embodied in several components, processes, or functions. Additional elements, components, processes, and/or functions may also be added without departing from the disclosure. It should also be noted FIGS. 2-7, 8A-8C, 9A-9C and/or 10-15 and its corresponding description in the present disclosure is not limited to dies and/or ICs. In some implementations, FIGS. 2-7, 8A-8C, 9A-9C and/or 10-15 and its corresponding description may be used to manufacture, create, provide, and/or produce devices and/or integrated devices. In some implementations, a device may include a die, a wafer, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another—even if they do not directly physically touch each other. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. The term “about ‘value X’”, or “approximately”, as used in the disclosure shall mean within 10 percent of the ‘value X’. For example, a value of about 1 or approximately 1, would mean a value in a range of 0.9-1.1.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. A device comprising:
a first die;
a second die coupled to the first die, the second die including a side portion and a backside portion; and
a polymer planarization layer coupled to the first die and the second die such that the polymer planarization layer is coupled to the side portion and the backside portion of the second die, wherein the polymer planarization layer includes an organic polymer.

2. The device of claim 1, further comprising a plurality of through polymer vias (TPVs) formed in the polymer planarization layer.

3. The device of claim 2, wherein the plurality of through polymer vias (TPVs) comprises a pitch in a range of about 10-20 micrometers (μm).

4. The device of claim 1, wherein the polymer planarization layer includes a photo-imageable polymer layer.

5. The device of claim 1, wherein the polymer planarization layer includes a self planarizing polymer.

6. The device of claim 1, wherein the polymer planarization layer includes a step up height of about 10 percent or less of a height of the second die.

7. The device of claim 1, wherein the polymer planarization layer includes (i) a Young's Modulus that is less than about 1 GigaPascal, (ii) a hardness that is less than about 1 GigaPascal.

8. The device of claim 1, further comprising a third die coupled to the second die, wherein the polymer planarization layer is coupled to the third die.

9. The device of claim 1, further comprising a third die coupled to the first die, the third die located laterally to the second die, wherein the polymer planarization layer is coupled to the third die.

10. The device of claim 1, further comprising:
a second polymer layer over the polymer planarization layer;
a first plurality of through polymer vias (TPVs) formed in the polymer planarization layer, the first plurality of through polymer vias (TPVs) coupled to the first die and the second polymer layer; and
a second plurality of through polymer vias (TPVs) formed in the polymer planarization layer, the second plurality of through polymer vias (TPVs) coupled to the second die and the second polymer layer.

11. The device of claim 1, further comprising a passive device in the polymer planarization layer.

12. The device of claim 11, wherein the passive device includes a capacitor and/or an inductor.

13. The device of claim 11, wherein the passive device is part of the second die.

14. The device of claim 1, wherein the device is incorporated into a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.

15. An apparatus comprising:
a first die;
a second die coupled to a first die, the second die including a side portion and a backside portion; and
means for self-planarizing layer coupled to the first die and the second die such that the means for self-planarizing layer is coupled to the side portion and the backside portion of the second die.

16. The apparatus of claim 15, further comprising a plurality of through polymer vias (TPVs) formed in the means for self-planarizing layer.

17. The apparatus of claim 6, wherein the plurality of through polymer vias (TPVs) comprises a pitch in a range of about 10-20 micrometers (μm).

18. The apparatus of claim 15, wherein the means for self-planarizing layer includes a photo-imageable polymer layer.

19. The apparatus of claim 15, wherein the means for self-planarizing layer includes a step up height of about 10 percent or less of a height of the second die.

20. The apparatus of claim 15, further comprising means for redistribution coupled to the means for self-planarizing layer, wherein the means for redistribution includes (i) a polymer layer and (ii) a plurality of interconnects.

21. A method for fabricating a device, comprising:
providing a wafer;
coupling a second die to the wafer, the second die including a side portion and a backside portion; and
forming a polymer planarization layer over the wafer and the second die such that the polymer planarization layer is coupled to the side portion and the backside portion of the second die, wherein the polymer planarization layer includes an organic polymer.

22. The method of claim 21, further comprising singulating the wafer into a first die.

23. The method of claim 21, further comprising forming a plurality of through polymer vias (TPVs) formed in the polymer planarization layer.

24. The method of claim 21, wherein the polymer planarization layer includes a self planarizing polymer.

25. The method of claim 21, wherein forming the polymer planarization layer includes forming the polymer planarization layer with a step up height of about 10 percent or less of a height of the second die.

26. The method of claim 25, further comprising forming a redistribution layer over the polymer planarization layer that includes the step up height.
